(19) United States
(12) Patent Application Publication
(10) Pub. No.: US 2010/0099050 A1
(43) Pub. Date: Apr. 22, 2010

(54) LIQUID RECOVERY APPARATUS, EXPOSURE APPARATUS, AND DEVICE MANUFACTURING METHOD

(75) Inventor: Tomohiko Yoshida, Utsunomiya-shi (JP)

Correspondence Address: ROSSI, KIMMS & McDOWELL LLP., 20609 Gordon Park Square, Suite 150, Ashburn, VA, 20147, US

(73) Assignee: CANON KABUSHIKI KAISHA, Tokyo (JP)

(21) Appl. No.: 12/580,877

(22) Filed: Oct. 16, 2009

(30) Foreign Application Priority Data
Oct. 17, 2008 (JP) 2008-268605

(51) Int. Cl. G03F 7/20; G03B 27/52

(52) U.S. Cl. 430/325; 355/30; 137/395

(57) ABSTRACT

A liquid recovery apparatus of the present invention is a liquid recovery apparatus 20 which recovers a liquid f, the liquid recovery apparatus 20 comprises a liquid recovery nozzle 6 having a porous plate 22, a container 23 configured to be filled with the liquid f, a recovery pipe 17 having one end and the other end, the one end being connected with the liquid recovery nozzle 6 and the other end being configured to be disposed inside the container 23, a pressure chamber 27 configured so that the liquid recovery nozzle 6 is disposed outside the pressure chamber 27 and the container 23 is disposed inside the pressure chamber 27, and a pressure regulator 30 configured to regulate an internal pressure of the pressure chamber 27.

### BACKGROUND OF THE INVENTION

1. Field of the Invention

The present invention relates to an immersion exposure apparatus which exposes a substrate via a liquid supplied between a final lens of a projection optical system and the substrate.

2. Description of the Related Art

In a method of manufacturing a semiconductor device which is constituted by an extremely-fine pattern such as an LSI or a ULSI, a reduction-type projection exposure apparatus which performs reduced projection to transfer a pattern formed on a mask onto a substrate to which a photosensitizing agent has been applied is used. In accordance with improvement of an integration density in the semiconductor device, a further miniaturization of the pattern is required, and a miniaturization of the exposure apparatus along with the development of a resist process has been performed.

As a means for improving a resolving power of an exposure apparatus, a method for shortening an exposure light wavelength and a method for enlarging a numerical aperture (NA) of a projection optical system are generally used.

With regard to the exposure light wavelength, i-line of 365 nm has been moved to ArF excimer laser light having an oscillation wavelength around 193 nm, and also EUV (Extreme Ultra violet) having an oscillation wavelength around 13.5 nm has been developed.

On the other hand, as an entirely different technology for improving the resolving power, a projection exposure method using an immersion method is attracting attention. Conventionally, a space between a final surface of the projection optical system and a surface of the substrate to be exposed (for example a wafer) was filled with a gas. However, in the immersion method, this space is filled with a liquid to perform projection exposure.

In the immersion exposure apparatus, for example pure water (a refractive index n is 1.44 with respect to light having a wavelength of 193 nm) is used as a liquid supplied in the space between the projection optical system and the wafer. When a maximum incident angle of a light beam that forms an image on a wafer in the immersion method is assumed to be equal to that of the conventional one, the resolving power of the immersion method improves 1.44 times as much as the conventional one even if a light source which has a wavelength identical to the conventional one is used. This is equivalent to increasing the numerical aperture (NA) 1.44 times as much as the projection optical system of the conventional method. Thus, according to the immersion method, it is possible to obtain the resolving power equal to or more than NA=1, which was conventionally impossible.

As one of methods for filling the space between a final surface of the projection optical system and a surface of the wafer with the liquid, there is a local-fill method in which a liquid flows only in the space between the projection optical system and the surface of the wafer.

The local-fill method supplies the liquid into a region opened between the final surface and the surface of the wafer and recovers the liquid by a liquid recovery mechanism using capillary phenomenon so as not to spill the liquid outside a stage. The capillary phenomenon is used for the liquid recovery mechanism because surface tension acting on a hole or a pipe with a small diameter overcomes a negative pressure at an inside of the recovery nozzle filled with the liquid to hold the liquid in the hole portion with a small diameter in a state where an outside of the recovery nozzle is filled with a gas.

When the liquid instead of the gas covers the small diameter hole, the surface tension acting on the interface is weakened. Therefore, the liquid is sucked into the recovery nozzle having a negative pressure through the small diameter hole to be recovered. When the small diameter hole is covered by the gas again, the small diameter hole holds the liquid by its surface tension to prevent the intrusion of the gas.

An exposure apparatus having such a liquid recovery apparatus is disclosed in for example Japanese Patent Laid-open No. 2006-60223.

A conventional liquid recovery apparatus as described above keeps a pressure inside a chamber filled with a liquid slightly lower than an external atmosphere. In order to keep an incompressible liquid to be a constant negative pressure, a negative pressure generating mechanism using hydraulic head pressure is preferably used.

This will be described with reference to FIG. 12. FIG. 12 is a schematic configuration diagram of a conventional liquid recovery apparatus 20′ provided with a negative pressure generating mechanism which is easily realizable.

As shown in FIG. 12, the liquid recovery apparatus 20′ includes a porous plate 22 having a plurality of holes with small diameters, a container 23, and a recovery pipe 17 covering an upper portion of the porous plate 22 and extending inside the container 23. The insides of the recovery pipe 17 and the container 23 are filled with a liquid f. An arrow indicated by reference numeral 100 denotes a direction of gravitational force. The container 23 is disposed so that a liquid surface 28 is in the direction of gravitational force 100 (at a lower side) with respect to a surface of the porous plate 22.

In this case, by a meniscus of the porous plate 22, a pressure Pc of the liquid f at an internal side is set to be smaller than a pressure Pm capable of being held by the surface tension acting on the interface between the porous plate 22 and the liquid f. The pressure Pc of the liquid f at the internal side can be obtained from expression (1) by the meniscus of the porous plate 22.

Pc=ρgh (1)

(ρ: liquid density, g: gravity acceleration, h: height (a height beginning at the porous plate))

According to the method, the liquid f flowed into the container 23 is dropped out of the upper portion of an end surface of the container 23. Therefore, the container 23 can be always held to be filled with the liquid f. At the same time, because the change of the liquid surface 28 is small, a constant hydraulic head pressure can be generated.

However, as represented by the above expression (1), in order to obtain a specific pressure Pc, the height h of the liquid surface 28 is limited to a specific height depending on the density ρ of the liquid f. Therefore, when the liquid recovery apparatus 20′ is applied to an immersion exposure apparatus, the location of the container 23 is to be limited.

When the liquid f is intruded from the outside of the liquid recovery nozzle 6 by the meniscus of the porous plate 22, the meniscus at a part of the porous plate 22 on which the liquid f contacts disappears. Subsequently, the liquid f passes through the hole of the porous plate 22 and flows into the container 23 via the recovery pipe 17. The flow of the liquid f generates a pressure loss ΔP and a pressure Pc of a slightly negative pressure with respect to the external atmosphere decreases by ΔP. Therefore, the recoverable flow rate is limited in a range of a pressure of Pc≧ΔP.

Thus, the limitation of the location of the container 23 causes the limitations of the locations of peripheral devices. Therefore, an optimal apparatus shape is lost and a footprint of the apparatus is enlarged.

The flow rate recovering the liquid f is limited by the pressure loss ΔP generated by the flow of the liquid f and a pressure loss ΔPcp generated at a portion of the porous plate 22. In order to suppress the pressure loss ΔP, the diameter of the recovery pipe 17 should be enlarged, the number of the recovery pipes 17 should be increased, or the liquid recovery nozzle 6 and the container 23 should be disposed in the vicinity of each other to suppress the length of the recovery pipe 17. Further, in order to suppress the pressure loss ΔPcp of the porous plate 22, the area of the porous plate 22 needs to be enlarged.

If it is difficult to enlarge the diameter of the recovery pipe 17 or enlarge the area of the porous plate 22, the liquid f may be ejected from the nozzle by the reduction of the recovering flow rate. Because stage velocity, acceleration, and moving distance are limited, the throughput and the apparatus performance may decrease. The limitations of the locations of the peripheral devices inside the apparatus influence the design of the apparatus, and the apparatus performance may be deteriorated or the footprint may be enlarged.

Further, a surfactant is used so that the meniscus of the liquid recovery apparatus can remove particles adhering to a wafer stage 10, a liquid supplying nozzle 5, or a porous plate 22. For example, in a case where the surfactant remains in a gap between the wafer stage 10 and the wafer 9 which is mounted on the wafer stage, when the surfactant intrudes into the meniscus formed at the porous plate 22 of the liquid recovery apparatus 20′, the surface tension of the liquid f is reduced. In this case, because a pressure Pm capable of being held by the meniscus decreases, the relation of Pm≧Pc breaks down. Therefore, the meniscus collapses and the gas g of the external atmosphere intrudes into the recovery pipe 17. When the inside of the recovery pipe 17 is occupied by the gas g instead of the liquid f, it is impossible to recover the liquid f.

### BRIEF SUMMARY OF THE INVENTION

The present invention provides a liquid recovery apparatus and an exposure apparatus which ease the limitation relating to a height of a liquid surface in a container to stably recover the liquid. Further, the present invention provides a device manufacturing method which stably improves a throughput.

A liquid recovery apparatus as one aspect of the present invention is a liquid recovery apparatus which recovers a liquid. The liquid recovery apparatus comprises a recovery port having a porous member, a container configured to be filled with the liquid, a pipe having one end and the other end, the one end being connected with the recovery port and the other end being configured to be disposed inside the container, a chamber configured so that the recovery port is disposed outside the chamber and the container is disposed inside the chamber, and a regulator configured to regulate an internal pressure of the chamber.

A liquid recovery apparatus as another aspect of the present invention is a liquid recovery apparatus which recovers a liquid. The liquid recovery apparatus comprises a recovery port having a porous member, a container configured to be filled with the liquid, a pipe having one end and the other end, the one end being connected with the recovery port and the other end being configured to be disposed inside the container, a detector configured to detect a pressure of the liquid near the recovery port, a liquid supply unit configured to supply the liquid to at least one of the recovery port and the pipe, and a flow controller configured to control a flow rate of the liquid supplied from the liquid supply unit based on a detected result of the detector.

A liquid recovery apparatus another aspect of the present invention is a liquid recovery apparatus which recovers a liquid. The liquid recovery apparatus comprises a recovery portion that includes a plurality of holes and that is configured to recover the liquid via the hole, a container configured to accumulate the liquid recovered by the recovery portion, a pipe having one end and the other end, the one end being connected with the recovery portion and the other end being configured to be disposed inside the container, a chamber which stores the container inside the chamber, and a regulator configured to regulate an internal pressure of the chamber. The regulator is configured to regulate the internal pressure of the chamber so that a pressure inside the recovery portion becomes a negative pressure with respect to a pressure around the recovery portion.

An exposure apparatus as another aspect of the present invention is an exposure apparatus which exposes a substrate via a liquid supplied between a final lens of a projection optical system and the substrate. The exposure apparatus comprises a liquid supply apparatus configured to supply the liquid between the final lens and the substrate, and the above liquid recovery apparatus.

A device manufacturing method as another aspect of the present invention comprises the steps of exposing a substrate using the above exposure apparatus, and developing the exposed substrate.

Further features and aspects of the present invention will become apparent from the following description of exemplary embodiments with reference to the attached drawings.

### BRIEF DESCRIPTION OF THE DRAWINGS

FIG. 1 is a schematic configuration diagram of a liquid recovery apparatus in Embodiment 1.

FIG. 2 is an enlarged diagram of a liquid recovery nozzle in Embodiment 1.

FIG. 3 is a schematic configuration diagram of a liquid recovery apparatus in Embodiment 2.

FIG. 4 is a schematic configuration diagram of a liquid recovery apparatus in Embodiment 3.

FIG. 5 is a schematic configuration diagram of a liquid recovery apparatus in Embodiment 4.

FIG. 6 is a schematic configuration diagram of a liquid recovery apparatus in Embodiment 5.

FIG. 7 is a schematic configuration diagram of a liquid recovery apparatus in Embodiment 6.

FIGS. 8A to 8E are schematic configuration diagrams of a liquid recovery apparatus in Embodiment 7.

FIGS. 9A to 9D are schematic configuration diagrams of a liquid recovery apparatus in Embodiment 8.

FIG. 10 is a schematic configuration diagram of a liquid recovery apparatus in Embodiment 9.

FIG. 11 is a schematic configuration diagram of a porous plate in Embodiment 10.

FIG. 12 is a schematic configuration diagram of a conventional liquid recovery apparatus.

FIG. 13 is a schematic configuration diagram of an immersion exposure apparatus in Embodiment 11.

FIG. 14 is a main enlarged diagram of an immersion exposure apparatus in Embodiment 11.

### DETAILED DESCRIPTION OF THE PREFERRED EMBODIMENTS

Exemplary embodiments of the present invention will be described below with reference to the accompanied drawings. In each of the drawings, the same elements will be denoted by the same reference numerals and the duplicate descriptions thereof will be omitted.

An exposure apparatus of the present invention uses for example ultraviolet light as exposure light, which is effective for all exposure methods and exposure apparatuses to which an immersion method that fills a space between a projection optical system and a substrate, for example a wafer, with a liquid is applied. For example, an exposure apparatus which projects to transfer a pattern of an original plate onto a substrate in a state where the substrate rests, or an exposure apparatus which performs a scanning exposure of a pattern of an original plate onto a substrate using slit light in a state where the substrate and the original plate are synchronously scanned can be included in such exposure apparatuses. Hereinafter, preferable embodiments of the present invention will be described with reference to the drawings, but the present invention is not limited to these embodiments.

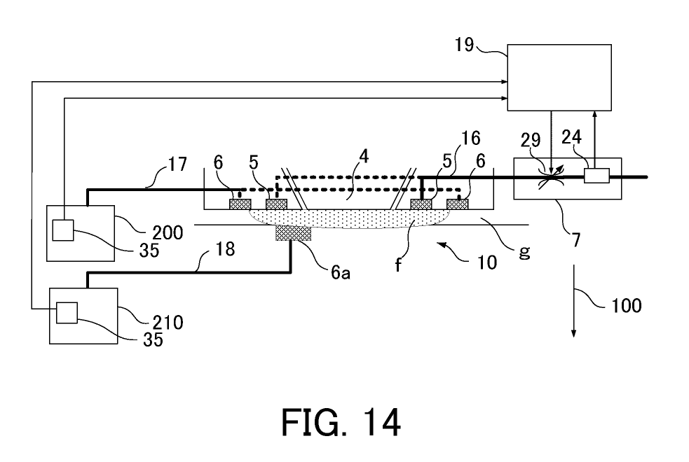

First, referring to FIGS. 13 and 14, a schematic configuration of an immersion exposure apparatus in the present embodiment will be described.

The exposure apparatus of the present embodiment is an immersion exposure apparatus which exposes a wafer 9 via a liquid f supplied between a final lens of a projection optical system 4 which is the closest to the wafer 9 that is a substrate and the wafer 9.

The immersion exposure apparatus is provided with a liquid supply apparatus which supplies the liquid f between the final lens and the wafer 9. The liquid supply apparatus includes a supply pipe 16, a valve 29, and an immersion controller 19.

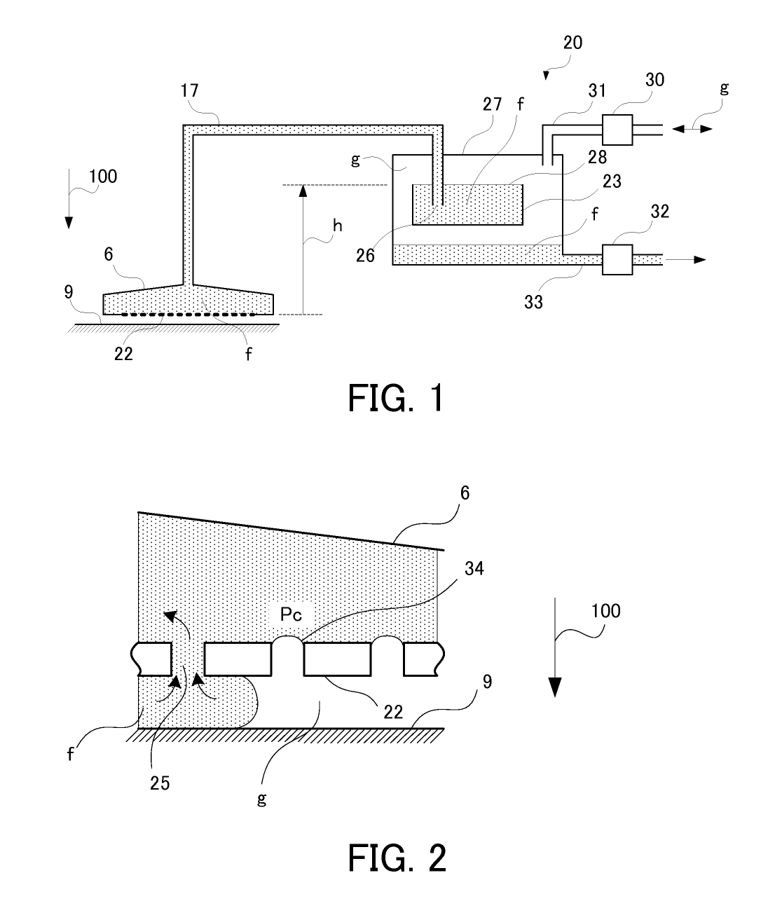

The supply pipe 16 is a liquid supply line which supplies the liquid f between the final lens and the wafer 9 (below the final lens). The valve 29 is provided in the middle of the supply pipe 16 that is a liquid supply line to control flow of the liquid f. The immersion controller 19 that is a controller controls opening and closing of the valve 29. The immersion exposure apparatus includes liquid recovery apparatuses 20 and 21 shown in FIGS. 1 to 11. The details of the immersion exposure apparatus shown in FIGS. 13 and 14 will be described later.

### Embodiment 1

First, a liquid recovery apparatus in Embodiment 1 of the present invention will be described. FIG. 1 is a schematic configuration diagram of a liquid recovery apparatus 20 in the present embodiment.

The liquid recovery apparatus 20 of the present embodiment is a recovery mechanism which recovers the liquid f, and mainly includes a liquid recovery nozzle 6 (a recovery port, or recovery portion), a recovery pipe 17 (a pipe), and a container 23 (a recovery container) provided inside a pressure chamber 27 (chamber). The liquid recovery nozzle 6 is provided with a porous plate 22 (porous member) having a plurality of holes. One end of the recovery pipe 17 is connected with the liquid recovery nozzle 6, and it recovers the liquid f via the porous plate 22. The liquid f recovered via the porous plate 22 is moved to the container 23 by passing through the recovery pipe 17.

An end (the other end) of the recovery pipe 17 constitutes an ejection port 26 which ejects the liquid f recovered via the porous plate 22. The ejection port 26 is open and is disposed inside the container 23. Therefore, the liquid f ejected from the ejection port 26 is recovered by the container 23. The container 23 is disposed inside the pressure chamber 27, and is open at an upper side compared with the ejection port 26 in a gravitational force direction 100 (arrow direction). The pressure chamber 27 is disposed outside the liquid recovery nozzle 6 and includes the container 23 inside it.

In FIG. 1, the recovery pipe 17 is installed from above the container 23 and is provided with the ejection port 26. However, the recovery pipe 17 can also be installed from a side surface of the container 23 or from under the container 23.

As shown in FIG. 1, the container 23 and the recovery pipe 17 are filled with the liquid f, and the porous plate 22 which is positioned at the end of the liquid recovery nozzle 6 holds the liquid f by a meniscus. The container 23 is filled with the liquid f up to its open surface (upper surface). When the liquid f is added from the recovery pipe 17 to an inside of the container 23 filled with the liquid f, the liquid f overflows from the open surface (upper surface) of the container 23, and it accumulates under the pressure chamber 27.

A structure for holding a liquid surface 28 using the open surface is not limited to the structure where the liquid f overflows from the upper surface as shown in FIG. 1. For example, a configuration where a hole is provided on a side surface of the container 23 or another pipe is extended from the side surface of the container 23 may also be applicable.

A pressure regulator 30 (a regulator) which regulates an internal pressure of the pressure chamber 27 is connected with the pressure chamber 27 via a pipe 31. The pressure regulator 30 is able to decrease or increase the internal pressure of the pressure chamber 27. Particularly, the pressure regulator 30 regulates the internal pressure of the pressure chamber 27 so that an internal pressure of the liquid recovery nozzle 6 filled with the liquid f shows a negative pressure and a value equal to or less than a bubble point with respect to an external pressure of the liquid recovery nozzle 6. The inside and the outside of the liquid recovery nozzle 6 are separated by the porous plate 22. The “bubble point” means a threshold value of a pressure where the meniscus in the porous plate 22 collapses.

The internal pressure of the pressure chamber 27 is regulated by ejecting a gas g outside the pressure chamber 27 or by introducing the gas g inside the pressure chamber 27. A gas having the same composition as that of an external environment or a nitrogen gas (N2) that is an inert gas is used as the gas g. However, the present invention is not limited to them, and other gases may also be used.

In the liquid recovery apparatus 20 shown in FIG. 1, a position of the liquid surface 28 in the container 23 is positioned at an upper direction as compared with the porous plate 22 in the gravitational force direction 100. In other words, the liquid surface 28 of the liquid f filled in the container 23 is positioned higher than the porous plate 22. When a height h of the liquid surface 28 with reference to a position of the porous plate 22 is used, a pressure Pc of the liquid f which is applied to an internal side of the meniscus portion can be derived from the above expression (1).

In the present embodiment, when the internal pressure of the pressure chamber 27 is equal to an atmospheric pressure around the porous plate 22, the pressure Pc shows a positive pressure. In other words, in a case where the internal pressure of the pressure chamber 27 and the external atmospheric pressure are equal to each other, when the height h of the liquid surface 28 with respect to the porous plate 22 has a positive value, the pressure Pc shows a positive pressure. On the other hand, when the height h of the liquid surface 28 with respect to the porous plate 22 has a negative value, the pressure Pc shows a negative value. Therefore, in order to move the liquid f from the porous plate 22 to the container 23 which is provided inside the pressure chamber 27, the pressure Pc inside the pressure chamber 27 needs to be set to a negative pressure.

As shown in FIG. 1, when the height h shows a positive value, in order to control the pressure Pc to be a negative pressure, the internal pressure of the pressure chamber 27 is controlled to be reduced by the pressure regulator 30 to set the pressure Pc to a negative pressure.

The liquid f overflowed from the container 23 and accumulated at the bottom of the pressure chamber 27 is ejected from the pressure chamber 27 via an ejection pipe 33 by an ejector pump 32.

Next, the liquid recovery nozzle in the present embodiment will be described in detail. FIG. 2 is an enlarged diagram of the liquid recovery nozzle 6 in the present embodiment.

As shown in FIG. 2, the wafer 9 is arranged so as to face the porous plate 22. When the liquid f is supplied between the porous plate 22 and the wafer 9 using a liquid supply apparatus (not shown), a meniscus 34 formed at the porous plate 22 collapses. When the meniscus 34 collapses, the liquid f supplied between the porous plate 22 and the wafer 9 is sucked by a negative pressure which is slightly larger than the pressure Pc, i.e. which is close to the atmospheric pressure. Therefore, the liquid f sucked via a hole 25 of the porous plate 22 is pressed out of the ejection port 26 via the recovery pipe 17 to be ejected to the container 23.

Because the container 23 maintains a fully-filled state so that the liquid surface 28 is constant, the position of the liquid surface 28 is only slightly changed by simply surface tension, and the liquid f overflows from the container 23. When the liquid f in a region between the porous plate 22 and the wafer 9 disappears, the meniscus 34 is formed at the porous plate 22 again. Therefore, the liquid recovery nozzle 6 is able to maintain a state where its inside is filled with the liquid f.

### Embodiment 2

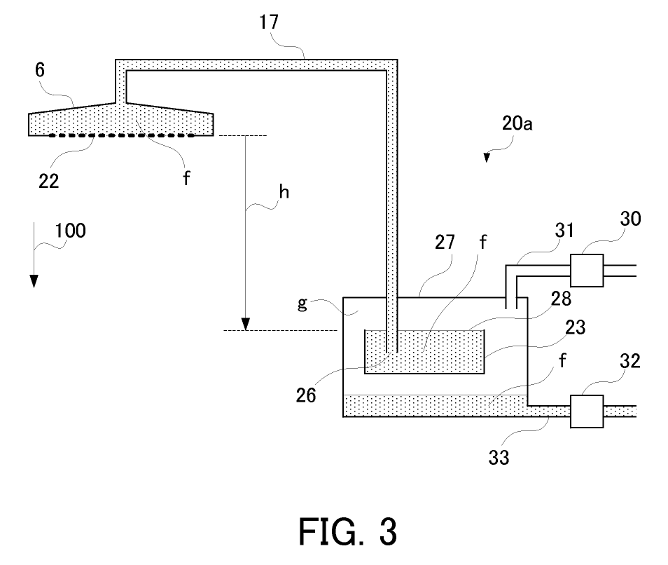

Next, a liquid recovery apparatus in Embodiment 2 of the present invention will be described. FIG. 3 is a schematic configuration diagram of a liquid recovery apparatus 20a in the present embodiment.

The liquid recovery apparatus 20a of the present embodiment is different from the liquid recovery apparatus 20 of Embodiment 1 in that a position of the liquid surface 28 with reference to a position of the porous plate 22 is disposed on a lower side in the gravitational force direction 100. In the liquid recovery apparatus 20a, because the liquid surface 28 of the liquid f accumulated in the container 23 is positioned at the lower side as compared with the porous plate 22, the height h of the liquid surface 28 with respect to the porous plate 22 shows a negative value.

Therefore, as represented by the above expression (1), the pressure Pc shows a negative value. Thus, even if the pressure Pc takes a negative value, in a case where the pressure Pc generated by the height h is unable to obtain a pressure required for recovering the liquid f, the pressure regulator 30 performs a control so that an inside of the pressure chamber 27 shows a negative pressure.

On the other hand, when the pressure Pc generated by the height h exceeds a pressure capable of being held by the meniscus 34, the pressure Pc is reduced up to the pressure capable of being held by the meniscus 34. In this case, the internal pressure of the pressure chamber 27 is controlled so that the inside of the pressure chamber 27 shows a positive pressure using the pressure regulator 30 to increase up to the pressure Pc where the meniscus 34 is able to be formed.

### Embodiment 3

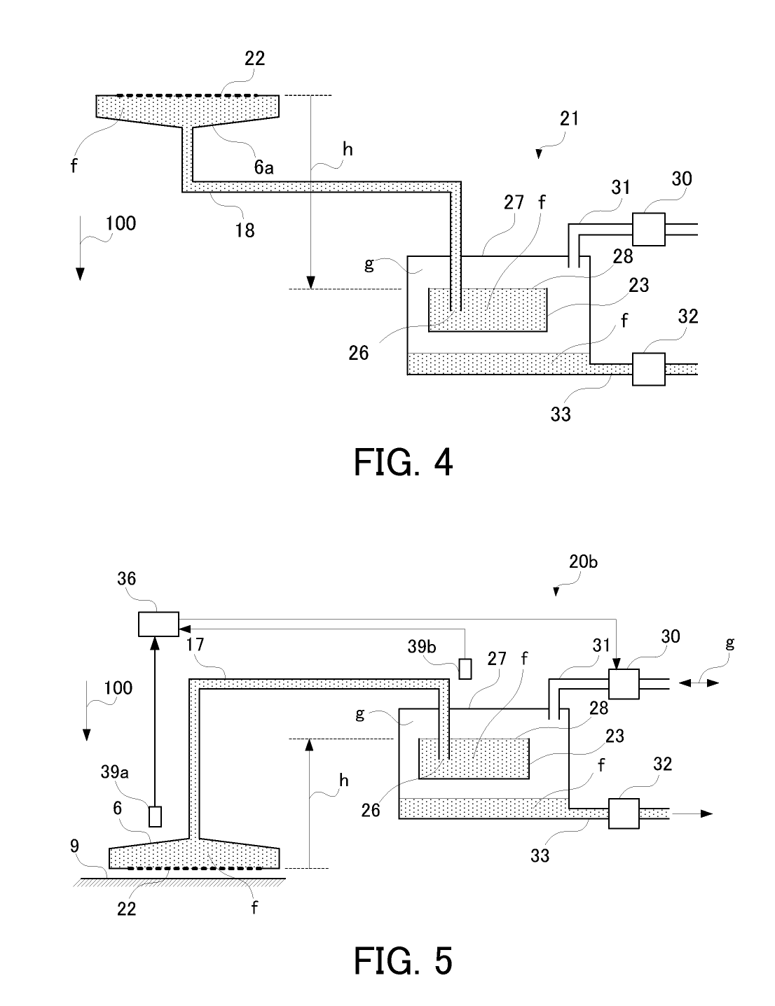

Next, a liquid recovery apparatus in Embodiment 3 of the present invention will be described. FIG. 4 is a schematic configuration diagram of a liquid recovery apparatus 21 in the present embodiment.

The liquid recovery apparatus 21 of the present embodiment is different from the liquid recovery apparatus 20a of Embodiment 2 (FIG. 3) in that a porous plate 22 of a liquid recovery nozzle 6a is disposed on an upper side in the gravitational force direction 100. In the present embodiment, a direction of the porous plate 22 is not limited to the upper side, but for example it can be disposed obliquely or in a lateral direction.

In the liquid recovery apparatus 21, similarly to Embodiment 2, the liquid surface 28 of the liquid f accumulated in the container 23 is positioned at the lower side as compared with the porous plate 22. Therefore, the height h of the liquid surface 28 with respect to the porous plate 22 shows a negative value.

Even if the pressure Pc takes a negative value, in a case where the pressure Pc generated by the height h is unable to obtain a pressure required for recovering the liquid f, the pressure regulator 30 performs a control so that the inside of the pressure chamber 27 shows a negative pressure.

On the other hand, when the pressure Pc exceeds a pressure capable of being held by the meniscus 34, the pressure Pc is reduced up to a pressure capable of being held by the meniscus 34. In this case, the internal pressure of the pressure chamber 27 is controlled so that the inside of the pressure chamber 27 is changed to a positive pressure using the pressure regulator 30 to increase up to a pressure Pc where the meniscus 34 is able to be formed.

### Embodiment 4

Next, a liquid recovery apparatus in Embodiment 4 of the present invention will be described. FIG. 5 is a schematic configuration diagram of a liquid recovery apparatus 20b in the present embodiment.

The liquid recovery apparatus 20b of the present embodiment is provided with atmospheric pressure sensors 39a and 39b and a pressure controller 36 in addition to the configuration of the liquid recovery apparatus 20 (FIG. 1) of Embodiment 1. The atmospheric pressure sensor 39a is disposed near the liquid recovery nozzle 6, and the atmospheric pressure sensor 39b is disposed around the pressure chamber 27. The pressure controller 36 calculates a differential pressure between both of a space near the liquid recovery nozzle 6 and a space around the pressure chamber 27, based on a atmospheric pressure detected by the atmospheric pressure sensors 39a and 39b.

The differential pressure calculated by the pressure controller 36 is outputted to the pressure regulator 30. The pressure regulator 30 regulates the internal pressure of the pressure chamber 27 so that a differential pressure between the internal pressure of the pressure chamber 27 and the external pressure near the liquid recovery nozzle 6 is constant.

Commonly, the pressure regulation by the pressure regulator 30 is controlled based on a difference between the external pressure near the pressure chamber 27 and the internal pressure of the pressure chamber 27. Therefore, if a differential pressure is generated between the pressure near the pressure chamber 27 and the pressure near the liquid recovery nozzle 6, the differential pressure is preferably corrected.

In the present embodiment, the pressure controller 36 corrects the differential pressure to control the pressure regulator 30. Therefore, the pressure regulator 30 is able to regulate the internal pressure of the pressure chamber 27 based on the differential pressure between the internal pressure of the pressure chamber 27 and the external pressure of the liquid recovery nozzle 6. As a result, according to the liquid recovery apparatus 20b of the present embodiment, a highly accurate pressure regulation can be performed.

Thus, the pressure regulator 30 corrects a pressure target value of the pressure chamber 27 based on the differential pressure between both spaces inputted from the pressure controller 36. The pressure target value is corrected by the differential pressure between both the spaces setting a value obtained by the atmospheric pressure sensor 39a as a reference of the atmospheric pressure of atmosphere.

The configuration of the present embodiment is particularly effective in a case where the liquid recovery nozzle 6 and the pressure chamber 27 are disposed in pressure spaces different from each other. The differential pressure between both the spaces can also be measured by using one differential pressure sensor without using two sensors of the atmospheric pressure sensors 39a and 39b.

The differential pressure correction in the present embodiment is preferably performed in combination with Embodiment 5 or Embodiment 6 which will be described later.

### Embodiment 5

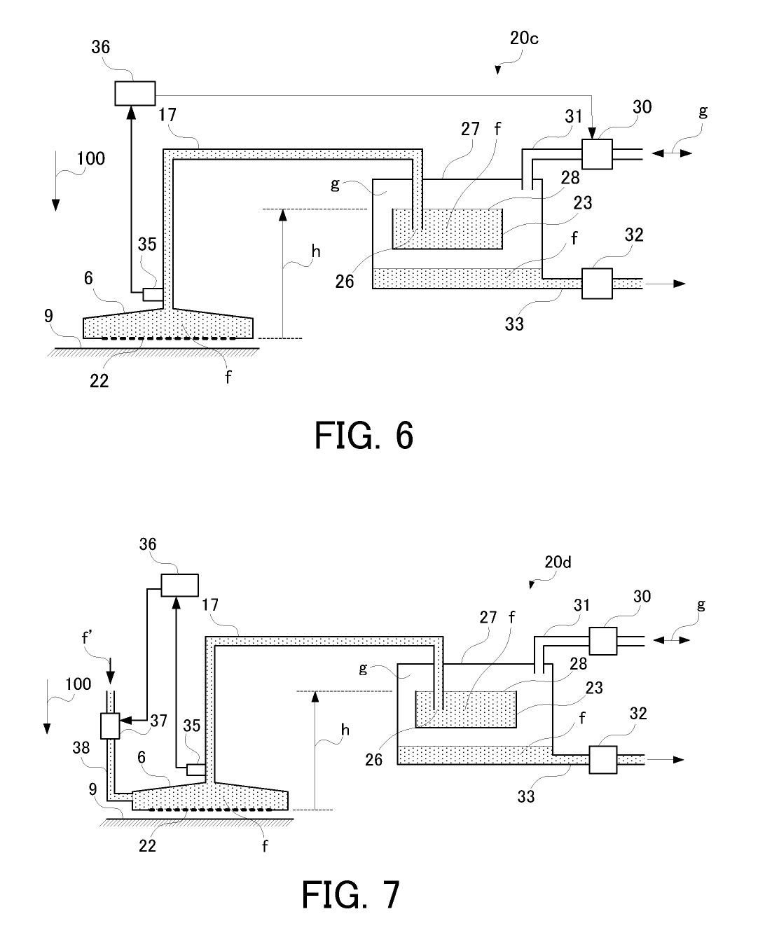

Next, a liquid recovery apparatus in Embodiment 5 of the present invention will be described. FIG. 6 is a schematic configuration diagram of a liquid recovery apparatus 20c in the present embodiment.

The liquid recovery apparatus 20c of the present embodiment is provided with a pressure sensor 35 (a detector) and a pressure controller 36 in addition to the configuration of the liquid recovery apparatus 20 (FIG. 1) of Embodiment 1. The pressure sensor 35 detects a pressure of the liquid f near the liquid recovery nozzle 6 (the porous plate 22). The pressure of the liquid f detected by the pressure sensor 35 is outputted to the pressure controller 36. The pressure controller 36 controls a target pressure of the pressure regulator 30 so that the pressure of the liquid f detected by the pressure sensor 35 becomes constant. The pressure regulator 30 regulates the internal pressure of the pressure chamber 27 based on a control signal from the pressure controller 36.

When the liquid f is recovered through the porous plate 22, a pressure loss is generated inside the recovery pipe 17 by the flow of the liquid f. The pressure regulator 30 regulates the internal pressure of the pressure chamber 27 so that the pressure of the liquid f detected by the pressure sensor 35 does not change. This purpose is not to change the pressure Pc inside the pressure chamber 27.

Although the pressure loss is generated particularly in the recovery pipe 17 by the flow of the liquid f, the recovery ability (flow rate) of the liquid f can be improved by controlling the internal pressure of the pressure chamber 27 so as to compensate the pressure loss.

### Embodiment 6

Next, a liquid recovery apparatus in Embodiment 6 of the present invention will be described. FIG. 7 is a schematic configuration diagram of a liquid recovery apparatus 20d in the present embodiment.

The liquid recovery apparatus 20d of the present embodiment is provided with a liquid supply apparatus 37 and a pipe 38 as a liquid supply unit in addition to the configuration of the liquid recovery apparatus 20c (FIG. 6) of Embodiment 5. The pipe 38 is connected with the liquid recovery nozzle 6, and the liquid supply apparatus 37 is connected with the liquid recovery nozzle 6 via the pipe 38. Further, in the liquid recovery apparatus 20d, a target to be controlled based on a pressure of the liquid f detected by the pressure sensor 35 (pressure detector) is different from that of the liquid recovery apparatus 20c of Embodiment 5. In other words, the pressure controller 36 of Embodiment 5 controls the internal pressure of the pressure chamber 27 while the pressure controller 36 of the present embodiment is used as a flow controller which controls the liquid supply apparatus 37.

In the present embodiment, when the liquid f is not recovered through the porous plate 22, the pressure controller 36 (flow controller) controls the flow rate of a liquid f′ supplied from the liquid supply apparatus 37 based on the detected result of the pressure sensor 35. The liquid supply apparatus 37 flows the liquid f′ at a predetermined flow rate based on a control signal inputted from the pressure controller 36. For example, the pressure controller 36 controls the flow rate of the liquid f′ so that a pressure detected by the pressure sensor 35 becomes constant.

The liquid f′ has substantially the same composition as that of the liquid f. In the embodiment, “substantially the same” includes not only a case where the compositions are identical but also a case where they are estimated as substantially the same.

As shown in FIG. 2, when the liquid f is supplied between the porous plate 22 and the wafer 9, the meniscus 34 formed at the porous plate 22 collapses. When the meniscus 34 collapses, the liquid f between the porous plate 22 and the wafer 9 is sucked into the liquid recovery nozzle 6 because of a negative pressure which is slightly higher than the pressure Pc, i.e. which is closer to the atmospheric pressure. The liquid f passing through the hole 25 of the porous plate 22 to be sucked is ejected so as to be pressed out of the ejection port 26 via the recovery pipe 17. In this case, because the flow rate of the liquid f flowing in the recovery pipe 17 increases, the pressure loss generated in the recovery pipe 17 increases and the movement of the liquid f is prevented.

In the present embodiment, the flow rate of the liquid f supplied from the pipe 38 to the liquid recovery nozzle 6 is regulated using the pressure controller 36 and the liquid supply apparatus 37 so that a pressure of the liquid f detected by the pressure sensor 35 becomes constant. According to such a control, the pressure loss generated by the recovery pipe 17 is suppressed and the liquid f can be stably recovered.

At the same time, in the present embodiment, since the liquid f is supplied into the liquid recovery nozzle 6, the liquid f inside the liquid recovery nozzle 6 or the liquid f inside the recovery pipe 17 and the container 23 can be always kept to be clean. Therefore, the generation of bacteria at each area can be suppressed. In particular, reducing the pollution inside the liquid recovery nozzle 6 which is positioned near the wafer 9 or the projection optical system 4 also leads to suppressing a process error represented by an exposure defect.

In the liquid recovery apparatus 20c of the present embodiment, the pipe 38 for supplying the liquid f is connected with the liquid recovery nozzle 6, but the embodiment is not limited to this. For example, the pipe 38 can also be connected with the recovery pipe 17 to suppress the pressure loss. The liquid f′ of the present embodiment may be supplied into either the liquid recovery nozzle 6 or the recovery pipe 17.

The pressure sensor 35 may also be configured so as to measure a pressure difference between the internal pressure of the liquid recovery nozzle 6 or the internal pressure of the recovery pipe 17 near the liquid recovery nozzle 6 and the external atmosphere of the porous plate 22.

### Embodiment 7

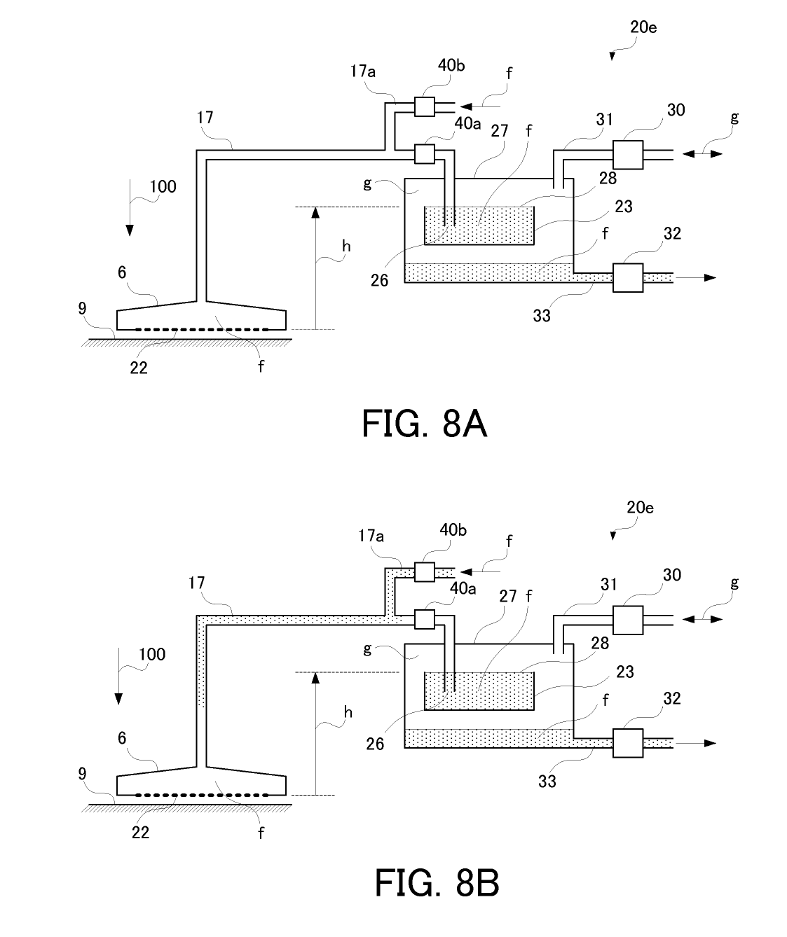

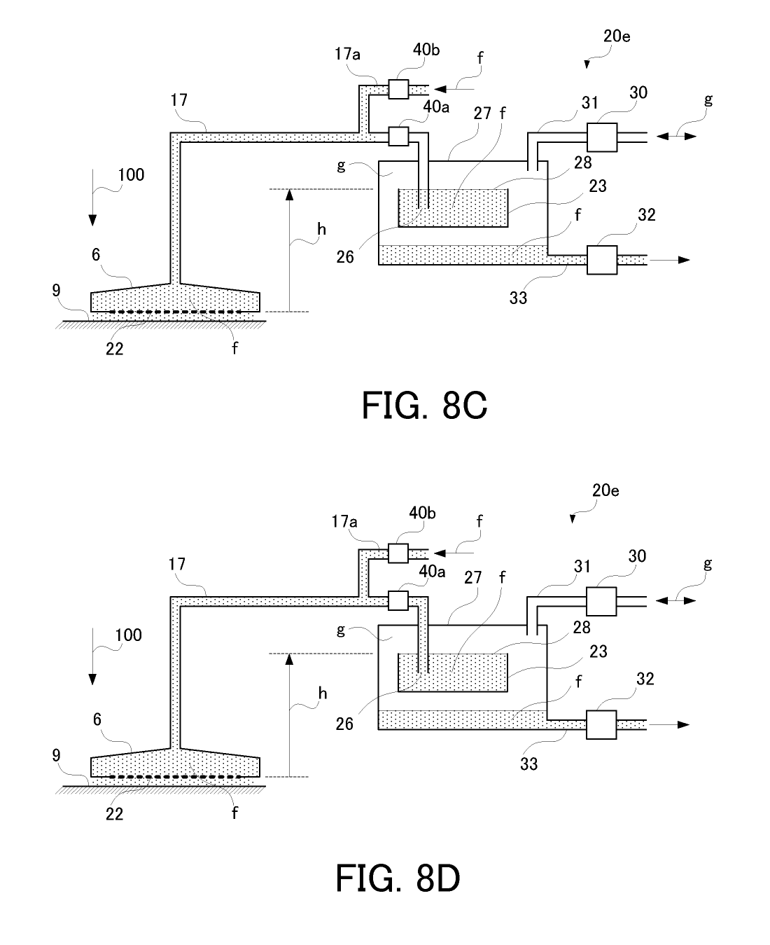

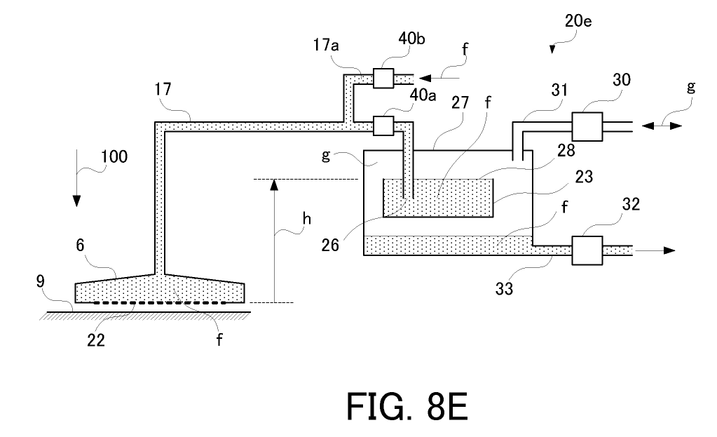

Next, a liquid recovery apparatus in Embodiment 7 of the present invention will be described. FIGS. 8A to 8E are schematic configuration diagrams of a liquid recovery apparatus 20e in the present embodiment. FIGS. 8A to 8E show processes for filling the recovery pipe 17 and the liquid recovery nozzle 6 with the liquid f in time series.

The liquid recovery apparatus 20e of the present embodiment is provided with valves 40a and 40b in addition to the configuration of the liquid recovery apparatus 20 (FIG. 1) of Embodiment 1. The valve 40a is disposed in the middle of the recovery pipe 17. The recovery pipe 17 is diverged at a side closer to the liquid recovery nozzle 6 than the valve 40a, and the valve 40b is disposed via a divergent pipe 17a.

As shown in FIG. 8A, in an initial state, neither the recovery pipe 17 nor the liquid recovery nozzle 6 is filled with the liquid f. In this state, the valve 40a is closed and the valve 40a is opened. Further, a liquid supply apparatus (not shown) presses to deliver the liquid f into the divergent pipe 17a. Because the valve 40b is open, the liquid f is supplied from the divergent pipe 17a to the recovery pipe 17 via the valve 40b.

As shown in FIG. 8B, because the valve 40b is closed, the liquid f moves in a direction of the liquid recovery nozzle 6 in the recovery pipe 17. Subsequently, as shown in FIG. 8C, the liquid f presses to eject a gas g existing inside the liquid recovery nozzle 6, and the inside of the liquid recovery nozzle 6 is filled with the liquid f.

The liquid f which passes through the porous plate 22 and is leaked to the wafer 9 side is recovered by a liquid recovery mechanism (not shown). A tray (not shown) which recovers the liquid may also be configured to move under the liquid recovery nozzle 6 instead of the wafer 9 or the wafer stage 10 to eject the liquid f to the tray.

Next, the valve 40a is opened. As shown in FIG. 8D, when the valve 40a is opened, the remaining gas g in a part between the valve 40a and the container 23 in the recovery pipe 17 is ejected to fill the recovery pipe 17 with the liquid f. Subsequently, the valve 40b is closed.

When the valve 40b is closed, the liquid f facing the porous plate 22 is recovered via the porous plate 22. At this time, the liquid recovery apparatus 20e becomes a state shown in FIG. 8E, and a process where the recovery pipe 17 and the liquid recovery nozzle 6 are filled with the liquid f is completed.

In the present embodiment, the liquid f flows from the recovery pipe 17 to the liquid recovery nozzle 6 which includes the porous plate 22, and the gas g inside the recovery pipe 17 along with the liquid f is ejected from the liquid recovery nozzle 6 via the porous plate 22 in order to fill the recovery pipe with the liquid f. Thus, according to the configuration of the present embodiment, the inside of the recovery pipe 17 can be easily filled with the liquid f.

### Embodiment 8

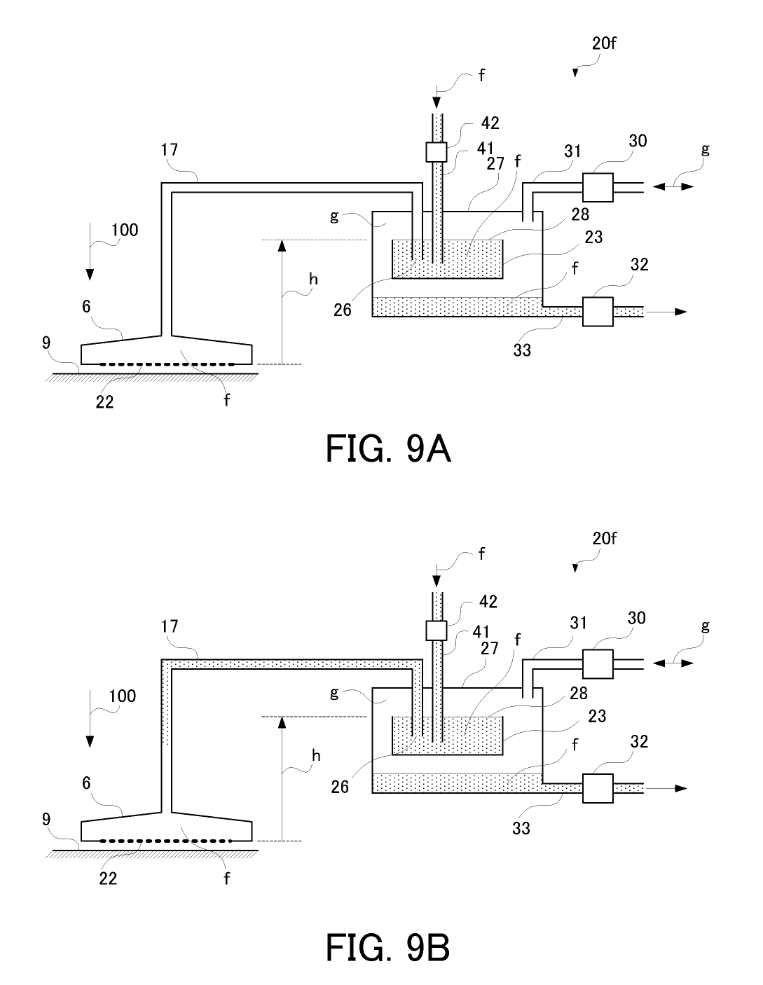

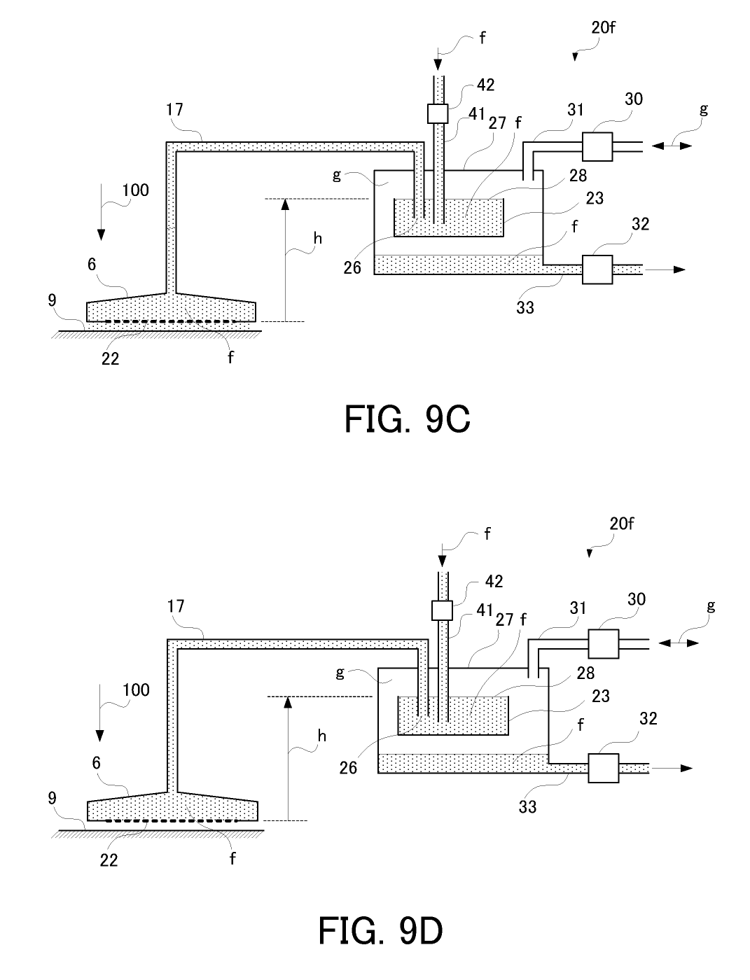

Next, a liquid recovery apparatus in Embodiment 8 of the present invention will be described. FIGS. 9A to 9D are schematic configuration diagrams of a liquid recovery apparatus 20f in the present embodiment. FIGS. 9A to 9D show processes for filling the recovery pipe 17 and the liquid recovery nozzle 6 with the liquid f in time series.

In FIGS. 9A to 9D, a valve 42 which opens and closes flow from a liquid supply apparatus (not shown) is disposed in the middle of a pipe 41, instead of the valves 40a and 40b of the liquid recovery apparatus 20e (FIGS. 8A to 8E) of Embodiment 7. Further, an end of the pipe 41 is inserted into the container 23 and the pipe 41 is disposed so that its end surface is always filled with the liquid f.

As shown in FIG. 9A, when the valve 42 is opened, the liquid f flows from a liquid supply apparatus (not shown) into the pipe 41, and the liquid f is supplied into the container 23. In this case, as shown in FIG. 9B, when the internal pressure of the pressure chamber 27 is increased by the pressure regulator 30, the liquid f is transferred from the recovery pipe 17 to the liquid recovery nozzle 6.

Gradually, the space inside the liquid recovery nozzle 6 is filled with the liquid f. The liquid f which passes through the porous plate 22 and is leaked to the wafer 9 side is recovered by a liquid recovery mechanism (not shown). Similarly to the case of Embodiment 7, the liquid f may also be ejected to a tray (not shown).

Subsequently, as shown in FIG. 9C, the internal pressure of the pressure chamber 27 is reduced up to a pressure where a meniscus is formed at the porous plate 22. Further, the valve 42 is closed to stop supplying the liquid f into the container 23.

As shown in FIG. 9D, the liquid f facing the porous plate 22 is recovered via the porous plate 22, and the process for being filled with the liquid f is completed.

### Embodiment 9

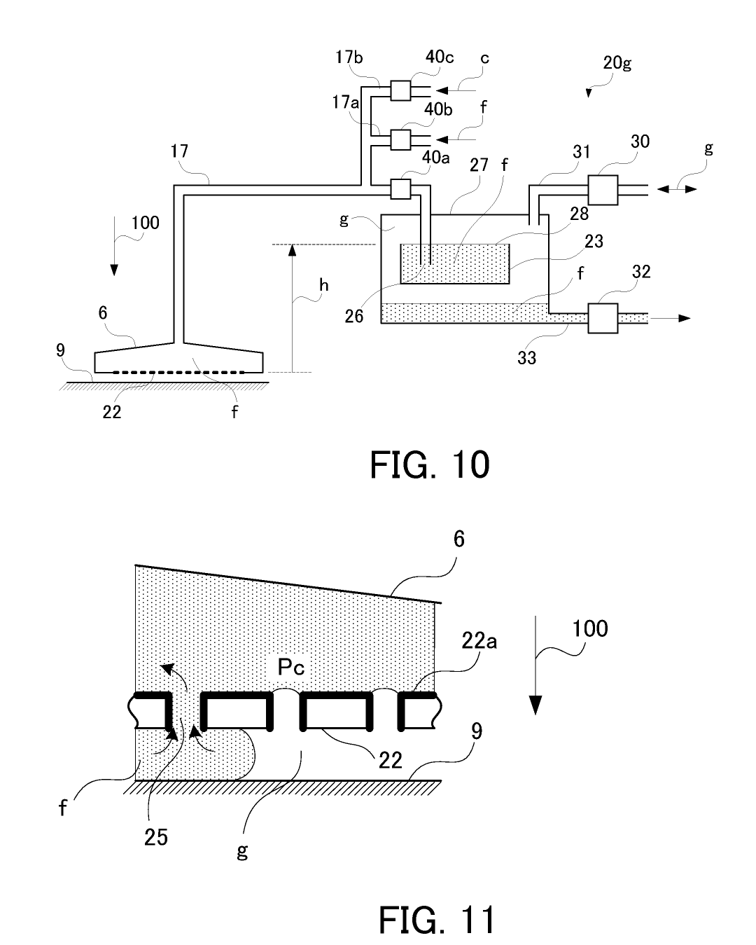

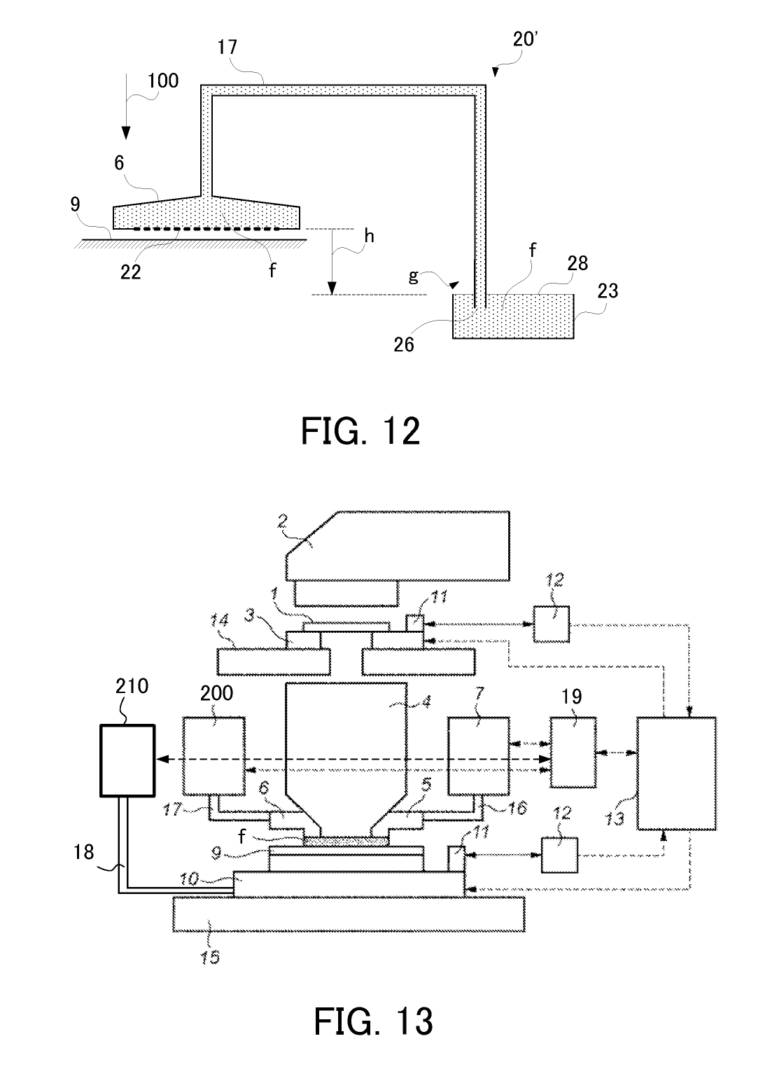

Next, a liquid recovery apparatus in Embodiment 9 of the present invention will be described. FIG. 10 is a schematic configuration diagram of a liquid recovery apparatus 20g in the present embodiment.

The liquid recovery apparatus 20g of the present embodiment is provided with a pipe 17b which supplies cleaning fluid c such as liquid including surfactant or fluorine-series solvent and a valve 40c in addition to the configuration of the liquid recovery apparatus 20e (FIGS. 8A to 8E) of Embodiment 7. The pipe 17b and the valve 40c are used as a cleaning fluid supply unit which flows the cleaning fluid c from the recovery pipe 17 to the liquid recovery nozzle 6.

When a resist piece stripped from a surface of the wafer 9 adheres to the porous plate 22 and a contaminant stripped from the porous plate 22 adheres onto the wafer 9 again, an exposure defect is generated. Therefore, in the present embodiment, in order to wash away or dissolve to remove the contamination which causes the exposure defect, the cleaning fluid c flows to clean the inside of the liquid recovery nozzle 6 or the porous plate 22 via the pipe 17b and the recovery pipe 17.

Specifically, the valve 40c is opened in a state where the valves 40a and 40b are closed, and a cleaning fluid supply apparatus (not shown) presses to deliver the cleaning fluid c to the pipe 17b. The delivered clearing fluid c passes through the pipe 17b and the recovery pipe 17 and is ejected via the liquid recovery nozzle 6 and the porous plate 22. The ejected fluid c is recovered by a recovery mechanism (not shown) on a wafer stage 10 or a liquid recovery mechanism (not shown) which is disposed around the liquid recovery nozzle 6. A tray may also be conveyed so as to eject the cleaning fluid c into the tray.

After the cleaning fluid c flows to the recovery pipe 17, sufficient rinsing is necessary. After the valve 40c is closed to stop supplying the cleaning fluid c, it is preferable that the valve 40b is opened and that the liquid f is delivered to rinse the cleaning fluid c. Further, it is preferable that the valve 40a is opened to rinse the cleaning fluid c which is mixed in the pressure chamber 27.

### Embodiment 10

Next, a liquid recovery apparatus in Embodiment 10 of the present invention will be described. FIG. 11 is a schematic configuration diagram of a porous plate 22 in the present embodiment.

As shown in FIG. 11, a surface of the porous plate 22 of the present embodiment is coated by a hydrophilic member 22a. Specifically, a surface which is positioned at an inside of the liquid recovery nozzle 6 and a side surface of the hole 25 of the porous plate 22 by which a meniscus is formed are coated by the hydrophilic member 22a having a contact angle smaller than 90 degrees, which is able to increase the force which is generated by the meniscus. Instead of using the hydrophilic member 22a, a hydrophilic surface treatment may also be performed. The hydrophilic member 22a is represented by heavy lines in FIG. 11.

On the other hand, with regard to a part which is positioned at an outside of the porous plate 22, a hydrophobic member having a contact angle of 90 degrees or larger is coated, or a hydrophobic surface treatment is performed to be able to effectively prevent the liquid f from adhering and remaining on a lower surface of the porous plate 22.

Thus, at the surface of the porous plate 22, it is preferable that a contact angle at a contact surface with the external atmosphere is larger than 90 degrees and that contact angles on a surface which is filled with the liquid f and a side surface of the hole 25 of the porous plate 22 are smaller than 90 degrees.

In each of the above embodiments, a case where the porous plate 22 is used for the liquid recovery nozzle 6 has been described. However, the present invention is not limited to this, and for example a porous member containing a porous body formed by sintering small particles may be used instead of the porous plate 22.

When the porous body is used, an inner surface of each small hole is preferably treated so as to show hydrophilic nature by using a material of the porous body or by performing a surface treatment.

### Embodiment 11

Next, an immersion exposure apparatus in Embodiment 11 of the present invention will be described. FIG. 13 is a schematic configuration diagram of the immersion exposure apparatus in the present invention. The immersion exposure apparatus of the present embodiment is provided with liquid recovery apparatuses 20 and 21 (liquid recovery portions 200 and 210). Each of the liquid recovery portions 200 and 210 includes a container 23, a pressure chamber 27 which includes the container 23, a pressure regulator 30 which regulates an internal pressure of the pressure chamber 27, and the like.

Light that has been emitted from an exposure light source (not shown) such as ArF excimer laser or EUV is supplied to an illumination optical system 2. The illumination optical system 2 illuminates a part of a reticle 1 that is an original plate by slit light having a cross-sectional shape which is formed by passing through a slit using light supplied from the exposure light source.

A reticle stage 3 (an original plate stage) holding the reticle 1 and a wafer stage 10 (a substrate stage) holding the wafer 9 (substrate) perform scanning movements in synchronization with each other while the reticle 1 is illuminated by the slit light. Such a synchronous scanning, as a result, can continuously form an image of whole pattern on the reticle 1 onto the wafer 9 via a projection optical system 4 to expose the resist which is applied onto a surface of the wafer 9.

The reticle stage 3 is supported by a platen 14 and the wafer stage 10 is also supported by a platen 15.

A two-dimensional position of the reticle stage 3 or the wafer stage 10 is measured in real time by a reference mirror 11 and a laser interferometer 12. The stage control apparatus 13 performs a positioning or a synchronous control of the reticle 1 (reticle stage 3) or the wafer 9 (wafer stage 10) based on the measured value.

A driving apparatus which adjusts, changes, or controls a position or a rotational direction in an upward and downward direction (vertical direction) or a tilt of the wafer 9 is embedded in the wafer stage 10.

During exposure, the wafer stage 10 is controlled so that an exposure area on the wafer 9 always matches a focal plane of the projection optical system 4 with high accuracy by the driving apparatus. The position (the position in the upward and downward direction and the tilt) of the surface on the wafer 9 is measured by an optical focus sensor (not shown) to be provided to a stage control apparatus 13.

A main body of the exposure apparatus is installed in an environmental chamber (not shown), and the environment around the main body of the exposure apparatus is kept to be a predetermined temperature.

Further, a conditioned air for which a temperature control is independently performed is blew into a space around the reticle stage 3, the wafer stage 10, and the laser interferometer 12, or a space around the projection optical system 4 to keep the environmental temperature with higher accuracy.

In the present embodiment, an immersion method for filling a space (a gap) between the final lens of the projection optical system 4 and the wafer 9 with a liquid is realized by a liquid supply nozzle 5 disposed above the wafer 9 and near the projection optical system 4 and the liquid recovery nozzle 6 disposed outside the liquid supply nozzle 5. Further, it is realized by a suction port (not shown) disposed inside the wafer stage 10.

The exposure apparatus of the present embodiment for example uses ultraviolet rays as exposure light, and it is effectively used for every exposure method and exposure apparatus where the immersion method filling the space between the projection optical system and the wafer that is a substrate with a liquid can be applied.

As such an exposure apparatus, for example an exposure apparatus which projects to transfer a pattern of an original plate onto a substrate in a state where the substrate is resting or an exposure apparatus which performs a scanning exposure of the pattern of the original plate onto the substrate using slit light while synchronously scanning the substrate and the original plate is included.

Next, referring to FIG. 14, a liquid supply apparatus and a liquid recovery apparatus in the immersion exposure apparatus of the present embodiment will be described in detail. FIG. 14 is a main enlarged diagram of the immersion exposure apparatus in the present embodiment.

The liquid supply nozzle 5 is connected with a liquid supply portion 7 via a supply pipe 16. The liquid supply portion 7 includes a flowmeter 24 and a valve 29. The valve 29 regulates a flow rate of the liquid f, and is able to stop the flow of the liquid f. The immersion control apparatus 19 controls the valve 29 so that the flow rate of the liquid f becomes constant based on information of the flowmeter 24.

The liquid supply portion 7 may includes for example a tank which accumulates the liquid, a pumping apparatus which pumps the liquid, a flow rate controller which controls the supplied flow rate of the liquid, and a control valve which controls supplying and stopping the liquid. Further, the liquid supply portion 7 preferably includes a temperature control apparatus for controlling a temperature of the supplied liquid f. The liquid supply portion 7 constitutes a liquid supply apparatus along with the liquid supply nozzle 5, the supply pipe 16, and the like.

The liquid recovery nozzle 6 is connected with a liquid recovery portion 200 via a recovery pipe 17 that is a recovery line. A liquid recovery nozzle 6a which is provided at the wafer stage 10 side is connected with a liquid recovery portion 210 via a recovery pipe 18 that is a recovery line. The liquid recovery portion 200 constitutes a liquid recovery apparatus along with the liquid recovery nozzle 6 and the recovery pipe 17. Similarly, the liquid recovery portion 210 constitutes a liquid recovery apparatus along with the liquid recovery nozzle 6a and the recovery pipe 18.

In the present embodiment, a plurality of liquid recovery portions 200 and 210 can be provided and recovery pipes 17 that are a plurality of recovery lines can also be connected with the liquid recovery portion 200. Each of the liquid recovery portions 200 and 210 includes a pressure regulator 30 which regulates a pressure of a pressure chamber and an ejector pump which ejects the recovered liquid.

The immersion control apparatus 19 receives information such as a current position, velocity, acceleration, a target position, and a moving direction of the wafer stage 10 from the stage control apparatus 13. The immersion control apparatus 19 provides the liquid supply portion 7 and the liquid recovery portions 200 and 210 with a control command such as start or stop of filling the space with the liquid or the flow rate based on the information.

The immersion control apparatus 19 monitors pressure information from the pressure sensors 35 of the liquid recovery portions 200 and 210 or the pressure regulator 30, and has a tolerance (a permissible limit) for determining the abnormality whether or not it shows a pressure state where the liquid f is unable to be recovered. When the information obtained from the pressure regulator 30 is beyond the tolerance (the permissible limit), the immersion control apparatus 19 that is a controller controls opening and closing of the valve 29 to stop supplying the liquid f between the final lens and the substrate (below the final lens).

The exposure apparatus of the present embodiment includes the plurality of liquid recovery portions 200 and 210, and each liquid recovery apparatus includes the pressure sensor 35 that is a pressure detector or the pressure regulator 30.

Further, the immersion control apparatus 19 determines the tolerance based on any one of, a plurality of, or all of the information of the pressure sensor 35 that is one or more pressure detectors.

The liquid f for immersion is selected from liquids which absorb the exposure light in small amounts, and preferably has substantially the same refractive index as that of a refractive optical element such as quartz or fluorite. Specifically, pure water, functional water, fluoride fluid (for example fluorocarbon) can be a candidate for the liquid f for immersion.

It is preferable that a dissolved gas has been adequately removed from the liquid f for immersion by using a degasifier in advance. This is because the generation of the bubble can be suppressed and the bubble can be absorbed in the liquid promptly even if the bubble is generated. For example with regard to nitrogen and oxygen contained in an environmental gas in large amount, if 80% or more of an amount of the gas dissolvable in the liquid is removed, the generation of the bubble can be adequately suppressed.

The exposure apparatus of the present embodiment may include a degasifier (not shown) to supply the liquid f to the liquid supply portion 7 while always removing the dissolved gas which exists in the liquid. For example, a vacuum degasifier that flows the liquid in one area separated by a gas-permeable film and that the other area is evacuated to remove the dissolved gas which exists in the liquid into a vacuum via the film is preferably used as a degasifier.

In order to remove pollution from the liquid supply nozzle 5, the liquid recovery nozzle 6, and the final lens of the projection optical system 4, a cleaning fluid c in which a surfactant or the like has been added can also be used.

A device (a semiconductor integrated circuit device, a liquid crystal display device, or the like) is manufactured by a process of exposing a substrate (a wafer, a glass plate, or the like) onto which a photosensitizing agent has been applied using the exposure apparatus in any one of the above embodiments, a process of developing the substrate, and other well-known processes.

According to the present embodiment, the limitation relating to the height of a liquid surface in a container can be eased to provide a liquid recovery apparatus and an exposure apparatus which stably recover the liquid. Therefore, according to the present embodiment, an apparatus footprint can be improved and the throughput can also be improved.

According to the present embodiment, a failure of the apparatus caused by liquid leakage or a failure caused by a short circuit or rust can be prevented before it occurs. Therefore, a liquid recovery apparatus and an exposure apparatus which perform a stable exposure process can be provided.

Further, according to the present embodiment, a device manufacturing method which stably improves the throughput can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-268605, filed on Oct. 17, 2008, which is hereby incorporated by reference herein in its entirety.

What is claimed is:

1. A liquid recovery apparatus which recovers a liquid, the liquid recovery apparatus comprising:
a recovery port having a porous member;
a container configured to be filled with the liquid;
a pipe having one end and the other end, the one end being connected with the recovery port and the other end being configured to be disposed inside the container;
a chamber configured so that the recovery port is disposed outside the chamber and the container is disposed inside the chamber; and
a regulator configured to regulate an internal pressure of the chamber.

2. A liquid recovery apparatus according to claim 1,
wherein the regulator regulates the internal pressure of the chamber so that an internal pressure of the recovery port shows a negative pressure and a pressure equal to or less than a bubble point with respect to an external pressure of the recovery port.

3. A liquid recovery apparatus according to claim 2,
wherein the regulator regulates the internal pressure of the chamber so that a differential pressure between the internal pressure of the chamber and the external pressure near the recovery port becomes constant.

4. A liquid recovery apparatus according to claim 1, further comprising:
a detector configured to detect a pressure of the liquid near the recovery port; and
a pressure controller configured to control the regulator so that the pressure of the liquid detected by the detector becomes constant.

5. A liquid recovery apparatus according to claim 1, further comprising a liquid supply unit configured to supply the liquid to at least one of the recovery port and the pipe.

6. A liquid recovery apparatus according to claim 1,
wherein the liquid flows from the pipe to the recovery port and a gas along with the liquid in the pipe is removed from the recovery port via the porous member to fill the pipe with the liquid.

7. A liquid recovery apparatus which recovers a liquid, the liquid recovery apparatus comprising:
a recovery port having a porous member;
a container configured to be filled with the liquid;
a pipe having one end and the other end, the one end being connected with the recovery port and the other end being configured to be disposed inside the container;
a detector configured to detect a pressure of the liquid near the recovery port;
a liquid supply unit configured to supply the liquid to at least one of the recovery port and the pipe; and
a flow controller configured to control a flow rate of the liquid supplied from the liquid supply unit based on a detected result of the detector.

8. A liquid recovery apparatus according to claim 7,
wherein the flow controller is configured to control the flow rate of the liquid supplied from the liquid supply unit so that the pressure of the liquid detected by the detector becomes constant.

9. A liquid recovery apparatus according to claim 1,
wherein the porous member contains a porous body which is formed by sintering particles.

10. A liquid recovery apparatus according to claim 1, further comprising a cleaning fluid supply portion configured to flow a cleaning fluid from the pipe to the recovery port.

11. A liquid recovery apparatus according to claim 1,
wherein on a surface of the porous member, a contact angle on a contact surface for external atmosphere is larger than 90 degrees, and contact angles on a surface filled with the liquid and a side surface of a hole of the porous member are smaller than 90 degrees.

12. A liquid recovery apparatus according to claim 1,
wherein a liquid surface of the liquid filling the container is positioned higher than the recovery port.

13. A liquid recovery apparatus which recovers a liquid, the liquid recovery apparatus comprising:
a recovery portion that includes a plurality of holes and that is configured to recover the liquid via the hole;
a container configured to accumulate the liquid recovered by the recovery portion;
a pipe having one end and the other end, the one end being connected with the recovery portion and the other end being configured to be disposed inside the container;
a chamber which stores the container inside the chamber; and
a regulator configured to regulate an internal pressure of the chamber,
wherein the regulator is configured to regulate the internal pressure of the chamber so that a pressure inside the recovery portion becomes a negative pressure with respect to a pressure around the recovery portion.

14. An exposure apparatus which exposes a substrate via a liquid supplied between a final lens of a projection optical system and the substrate, the exposure apparatus comprising:
a liquid supply apparatus configured to supply the liquid between the final lens and the substrate; and
a liquid recovery apparatus configured to recover the liquid,
wherein the liquid recovery apparatus comprises:
a recovery port having a porous member;
a container configured to be filled with the liquid;
a pipe having one end and the other end, the one end being connected with the recovery port and the other end being configured to be disposed inside the container;
a chamber configured so that the recovery port is disposed outside the chamber and the container is disposed inside the chamber; and
a regulator configured to regulate an internal pressure of the chamber.

15. An exposure apparatus according to claim 14,
wherein the liquid supply apparatus includes a liquid supply line, a valve provided in the middle of the liquid supply line, and a controller configured to control opening and closing of the valve, and
wherein when information obtained from the regulator is beyond a permissible limit, the controller controls opening and closing of the valve to stop supplying the liquid between the final lens and the substrate.

16. A device manufacturing method comprising the steps of:
exposing a substrate using an exposure apparatus; and
developing the exposed substrate,
wherein the exposure apparatus is configured to expose the substrate via a liquid supplied between a final lens of a projection optical system and the substrate, the exposure apparatus including:
a recovery port having a porous member;
a container configured to be filled with the liquid;
a pipe having one end and the other end, the one end being connected with the recovery port and the other end being configured to be disposed inside the container;
a chamber configured so that the recovery port is disposed outside the chamber and the container is disposed inside the chamber; and
a regulator configured to regulate an internal pressure of the chamber.
